(19) United States
(12) Patent Application Publication
(10) Pub. No.: US 2018/0041003 A1
(43) Pub. Date: Feb. 8, 2018

(54) CHIP ON CHIP (COC) PACKAGE WITH INTERPOSER

(71) Applicant: Intel Corporation, Santa Clara, CA (US)

(72) Inventors: Juan E. Dominguez, Chandler, AZ (US); Myung Jin Yim, San Jose, CA (US)

(21) Appl. No.: 15/231,510

(22) Filed: Aug. 8, 2016

(51) Int. Cl. H01S 5/022; H01L 23/00

(52) U.S. Cl. CPC H01S 5/02248; H01S 5/02272; H01L 24/17; H01L 24/81; H01L 2924/1426; H01L 2924/12042; H01L 2224/13147; H01L 2224/16145; H01L 2224/16227; H01L 2224/81203; H01L 2924/2064

(57) ABSTRACT

Embodiments herein may relate to a chip-on-chip (CoC) package that includes a first integrated circuit (IC) die with an active side coupled with an active side of a second IC die. The CoC package may further include a substrate with a conductive metal post extending from a side of the substrate. An interposer may be positioned between, and coupled with the conductive metal post and the active side of the first IC die such that an area between an inactive side of the second IC die and the substrate is free of the interposer. Other embodiments may be described and/or claimed.

### TECHNICAL FIELD

The present disclosure relates generally to the field of chip-on-chip (CoC) packages, and more specifically to the use of an interposer in conjunction with the CoC package.

### BACKGROUND

Some CoC packages may require complex assembly integration for attaching the two integrated circuit (IC) die together to form the CoC package or to attach the CoC package to a substrate. In embodiments where one or both of the IC die is a laser such as a silicon (Si) laser, the laser portion of the CoC package may require thermal compression bonding as will be discussed in greater detail below. The thermal compression may need to be performed without having a copper (Cu) post or bump directly on the Si laser to prevent potential Cu contamination to the Si laser.

Additionally, in some legacy embodiments where a Cu post is used to couple the CoC package to the substrate, such a post may have a limited z-height (that is, height as measured from the substrate to the CoC package). Going beyond the limited z-height may cause package failure due to delamination of the package or extrusion of the Cu post.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 depicts an example apparatus that includes a CoC package coupled with a substrate, in accordance with various embodiments.

FIGS. 2a and 2b depict an example interposer substrate and substrate of an apparatus, in accordance with various embodiments.

FIG. 3 depicts an example interposer, in accordance with various embodiments.

FIGS. 4a-4c depict example stages of the manufacture of an apparatus similar to the example apparatus of FIG. 1, in accordance with various embodiments.

FIGS. 5a-5c depict alternative example stages of the manufacture of an apparatus similar to the example apparatus of FIG. 1, in accordance with various embodiments.

FIG. 6 depicts an example process for manufacturing an apparatus similar to the apparatus of FIG. 1 or 4c, in accordance with various embodiments.

FIG. 7 depicts an example process for manufacturing an apparatus similar to the apparatus of FIG. 1 or 5c, in accordance with various embodiments.

FIG. 8 is an example computing device that may include one or more anchoring pins, in accordance with various embodiments.

### DETAILED DESCRIPTION

Embodiments herein may relate to an apparatus comprising: a CoC package that includes a first IC die with an active side coupled with an active side of a second IC die. In embodiments, the first IC die may be a Si laser transmit (Tx) die, and the second IC die may be a Si laser Tx IC die as described herein. The apparatus may further include a substrate and a conductive metal post extending from a side of the substrate. In embodiments the conductive metal post may be a copper (Cu) post. The apparatus may further include an interposer positioned between, and coupled with the conductive metal post and the active side of the first IC die, wherein an area between an inactive side of the second IC die and the substrate is free of the interposer. Other embodiments may be described and/or claimed.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

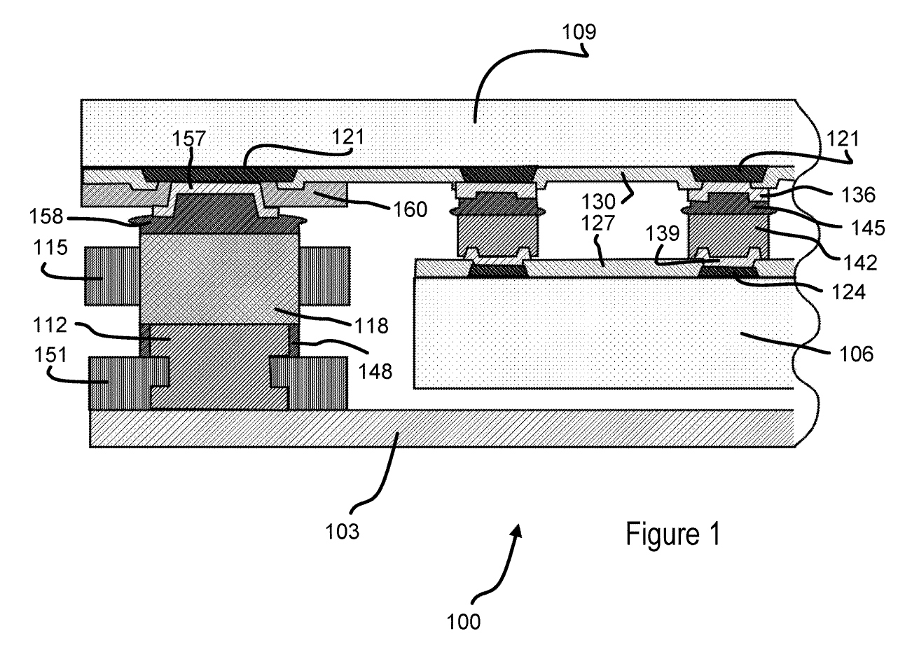

FIG. 1 depicts an example apparatus 100 that includes a CoC package coupled with a substrate 103, in accordance with various embodiments. It will be understood that each and every element of FIG. 1 may not be labeled for the sake of clarity and ease of understanding the Figure; however, unlabeled elements that are shaped and shaded similarly to labeled elements may be considered to be similar or identical to the labeled elements.

In embodiments, the CoC package may include a first die 106 coupled with a second die 109. In embodiments, the die 106 may be a transmit (Tx) integrated circuit (IC) die 106. The die 109 may be a Tx die 109. The Tx die 109 may include a laser such as an Si laser or some other type of laser or active device and in some embodiments may be described as a laser Tx die. The Tx IC die 106 may include one or more driver and/or biasing circuits to provide power, control, biasing, and/or some other type of signals to the Tx die 109, and in some embodiments may be described as a laser Tx driver. In other embodiments, the die 106 or 109 may be some other type of die such as a processor, a memory, or some other type of electronic die or circuit.

In embodiments, the Tx IC die 106 may include one or more die pads such as Tx IC die pad 124. The Tx IC die pad(s) 124 may be coupled with an internal element of the Tx IC die 106 such as a processor or some other element or circuit. The Tx IC die pad(s) 124 may be to carry communication signals, electrical signals, data signals, thermal energy, and/or some other type of signal to or from the Tx IC die 106. In embodiments, the Tx IC die pad(s) 124 may include a conductive metal such as gold, copper, or some other type of conductive metal.

The Tx IC die 106 may further include a layer such as a passivation layer 127. The passivation layer 127 may be at least partially dielectric such that it may act as an electrically insulative layer. The passivation layer 127 may also act as a solder resist layer to protect the Tx IC die 106 during coupling of the Tx IC die 106 to the Tx die 109. In some embodiments, the passivation layer 127 may have one or more additional or alternative functions as would be understood by one in the art. In embodiments, the passivation layer 127 may be formed of a material such as a polyimide, polybenzoxazole (PBO) film, silicon glass based polymers, and/or similarly applied silicon glasses.

The Tx IC die 106 may further include an underbump metallization layer 139. The underbump metallization layer 139 may be configured to couple with a Cu bump such as Cu bump 142 that physically couples the Tx IC die 106 and the Tx die 109. Specifically, the underbump metallization layer 139 may be positioned on the Tx die pad(s) 124 and aid adherence of the Tx die pad(s) 124 to the Cu bump(s) 142. In embodiments, the underbump metallization layer 139 may be formed of and/or include a seed (which could be Cu, a Cu alloy, and/or some other conductor), a barrier, and/or an adhesion layer (which could be titanium (Ti), titanium-tungsten (TiW), nickel (Ni) and/or some other material with similar properties).

In embodiments, the Tx die 109 may additionally include one or more Tx die pads 121, which may be similar to the Tx IC die pad(s) 124. That is, the Tx die pads 121 may be to carry electrical signals, data signals, and/or some other type of signal to or from the Tx die 109. The Tx die 109 may additionally include a passivation layer 130, which may be similar to passivation layer 127. For example, the passivation layer 130 may be formed of a similar material and/or have a similar function to passivation layer 127. In other embodiments, the passivation layer 130 may be formed from a different material and/or have a different function than passivation layer 127. In some embodiments, the Tx die 109 may further include an underbump metallization layer 136, which may be similar to underbump metallization layer 139.

In embodiments, the Tx IC die 106 may be coupled to the Tx die 109 via one or more solder joints. Each solder joint may include a Cu bump such as Cu bump 142, and a lead-free (LF) solder joint 145. In embodiments, the LF solder joint 145 may include a lead-free solder such as a tin-copper (SnCu), tin-silver-copper (SnAgCu), and/or tin-silver (SnAg) solder, or some other type of solder.

In embodiments, the solder joints may be configured to carry electrical signals, communication signals, data signals, thermal energy, and/or some other type of signal or energy between the Tx die 109 and the Tx IC die 106. In embodiments, the Tx IC die 106 may be coupled with the Tx die 109 via a process known as thermal compression bonding using non-conductive paste (TCNCP). Specifically, in embodiments the Cu bump(s) 142 may include LF solder paste at the end of the Cu bump(s). The LF paste may be formed of one of the LF solders described above with respect to LF solder joint 145. Specifically, the Cu bump(s) 142 may be an element of the Tx IC die 106, and the Tx IC die 106, with the Cu bump(s) 142 and the LF paste, may be positioned on the Tx die 109 such that the LF paste comes in contact with the underbump metallization layer 136. The Tx IC die 106 may then have force applied to the side of the Tx IC die 106 opposite the side with Tx IC die pads 124, and heat may be applied such that the LF solder paste reflows to form the LF solder joint(s) 145.

In embodiments, the apparatus 100 may further include an interposer that may include an interposer substrate 115 and an interposer conductor 118. The interposer substrate 115 may be some form of dielectric material such as silicon. The interposer may have one or more conductors such as interposer conductor 118 dispersed therein. The interposer conductor 118 may be some conductive metal such as copper, gold, or some other type of conductive metal. Specifically, the interposer conductor 118 may be configured to carry one or more electric signals, data signals, communicative signals, and/or thermal energy from one side of the interposer to another. In some embodiments the interposer substrate 115 may have a z-height of approximately 15 to approximately 35 microns. The interposer conductor 118 may have a z-height of approximately 10 to approximately 30 microns. As used herein, z-height may refer to a distance as measured from the substrate 103 to the Tx die 109. An alternative way to refer to z-height may be a distance as measured in a direction perpendicular to a side of the substrate 103, specifically the side to which the Cu post 112 is coupled.

In embodiments, the Tx die 109 may include an underbump metallization layer 157, which may be similar to underbump metallization layers 136 and/or 139. The Tx die 109 may further include a polyimide layer 160, which may be similar to passivation layer 130 and/or 127. In embodiments, the polyimide layer 160 may be approximately 5 to approximately 10 micron Si glass or Si containing organic glass.

The interposer conductor 118 may be coupled with the underbump metallization layer 157 via an LF-solder joint 158 which may be similar to LF solder joint 145. In embodiments, the LF solder joint 158 may be formed of one or more of the LF solder materials described above. In some embodiments, the LF solder material of LF solder joint 158 may be the same as LF solder joint 145, and in other embodiments the LF solder material of LF solder joint 158 may be different than the LF solder joint 145.

On the opposite side of the interposer, the interposer conductor 118 may be coupled with a Cu post such as Cu post 112. In embodiments, the Cu post 112 may have a z-height between approximately 25 micrometers (urn) and approximately 40 urn.

In embodiments, the Cu post 112 may be at least partially covered by a solder resist layer 151. The solder resist layer 151 may be approximately 15 to approximately 30 microns in thickness. Generally, the solder resist may be used to protect other areas of the substrate from exposed Cu oxidation and prevent shorting between signals.

In embodiments, the Cu post 112 may be coupled with the interposer, and particularly the interposer conductor 118, via a solder wick 148. The solder wick 148 may be formed of an LF solder material as described above, or some other type of solder material. The solder wick 148 may be desirable because the relative melting points of the interposer conductor 118 and the Cu post 112 may be relatively high; therefore directly adhering the interposer conductor 118 and the Cu post 112 may be difficult to do without damaging other elements of the apparatus 100. However, if a solder wick 148 includes a material with a relatively low melting point, then it may be possible to adhere the Cu post 112 and the interposer conductor 118 directly to one another via the solder wick 148 without damaging other elements of the apparatus 100.

As can be seen in FIG. 1, the interposer (e.g., the element formed from the interposer conductor 118 and the interposer substrate 115) may be useful for a variety of reasons. First, the interposer may help to provide a functional extension to the Cu post 112 without actually extending the z-height of the Cu post 112. As discussed above, extending the z-height of the Cu post 112 may cause failure of the apparatus 100 due to, for example, delamination of one or more layers of the apparatus 100 and/or physical errors during the extrusion process of the Cu post 112.

Additionally, the interposer conductor 118 may serve to isolate the Cu post 112 from the Tx die 109 to reduce and/or eliminate the Cu contamination of the Tx die 109. The underbump metallization layer 157 and/or the LF solder joint 158 may additionally serve to isolate the interposer conductor 118 and/or the Cu post 112 from the Tx die 109. The LF solder joint(s) 145 and/or the underbump metallization layer(s) 136 may similarly isolate the Tx die 109 from the Cu bump(s) 142 to reduce or eliminate Cu contamination of the Tx die 109. It will be understood that although the LF solder may be SnCu and/or SnAgCu, and include some amount of Cu, the amount of Cu in the LF solder may be low enough that the risk of Cu contamination to the Tx die 109 from the LF solder joint(s) 158 and/or 145 may be relatively low.

It will be understood that, although not shown, underfill may be present in the spaces between the substrate 103 and the Tx die 109, the substrate 103 and the Tx IC die 106, and/or the Tx die 109 and the Tx IC die 106. In embodiments, the underfill may include a dielectric material such as epoxy or some other material. In some embodiments, the underfill may be a capillary underfill, which may indicate that the underfill was deposited subsequent to coupling of the CoC package to the substrate 103 and/or the Tx die 109 to the Tx IC die 106.

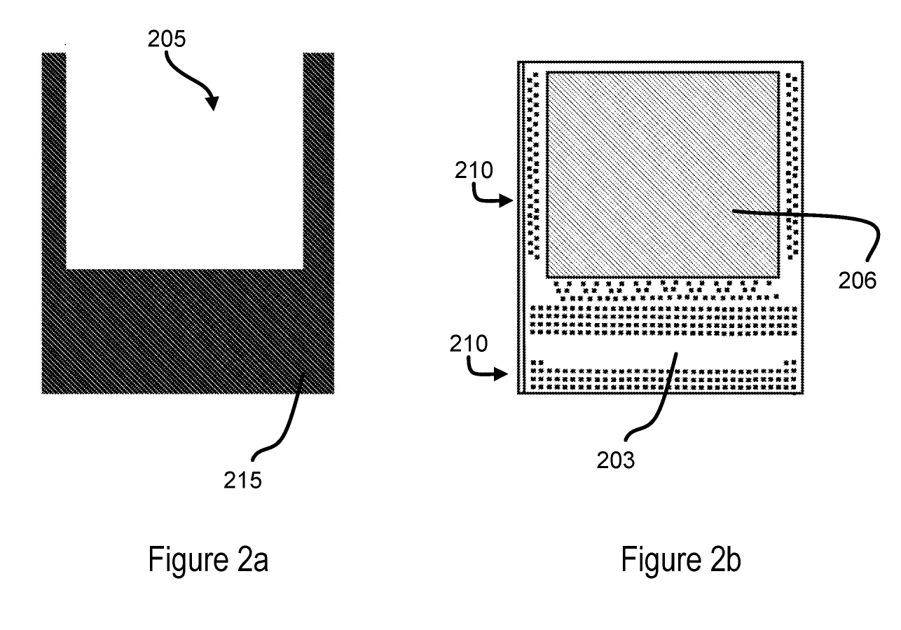

FIGS. 2a and 2b depict an example interposer substrate and substrate of an apparatus, in accordance with various embodiments. Specifically, FIG. 2a depicts an interposer substrate 215 which may be similar to interposer substrate 115. The view of FIG. 2a may be a top-down view of the interposer substrate 215, for example, a view from the top of the page of FIG. 1 to the bottom of the page of FIG. 1. The interposer substrate 215 may include a cut-out portion 205.

FIG. 2b may depict a substrate 203 of an apparatus, which may be similar to substrate 103. The substrate 203 may include a plurality 210 of Cu posts such as Cu post 112. FIG. 2b further depicts an IC Tx die 206, which may be similar to IC Tx die 106. As shown in FIG. 1, the IC Tx die 206 may not be directly coupled with the substrate 203. However, as can be seen in FIG. 1, the interposer substrate 215 may be generally coplanar with the IC Tx die 206. As such, when the interposer substrate 215 is coupled with the substrate 203, the IC Tx die 206 may be positioned within the cut-out portion 205 of the interposer substrate 215. By positioning the IC Tx die 206 within the cut-out portion 205 of the interposer substrate 215, the interposer may be used in conjunction with an apparatus such as apparatus 100 without substantially increasing the z-height of the apparatus 100 due to the use of the interposer.

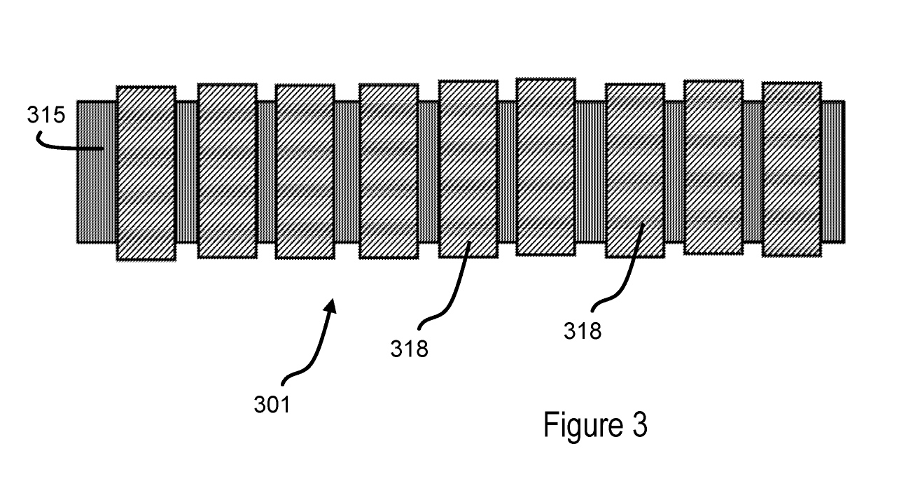

FIG. 3 depicts an example interposer 301, in accordance with various embodiments. In embodiments, the interposer 301 may include an interposer substrate 315, which may be similar to interposer substrate 115. The interposer 301 may further include a plurality of interposer conductors 318, which may be similar to interposer conductors 118. Although only a single Cu post 112 is depicted in FIG. 1 electrically coupled with a single die pad 121 of the Tx die 109, in some embodiments the Tx die 109 may have a plurality of die pads similar to die pad 121 coupled with a plurality of Cu posts similar to Cu post 112. Respective die pads and Cu posts may be coupled with the respective interposer conductors 318 of the interposer 301.

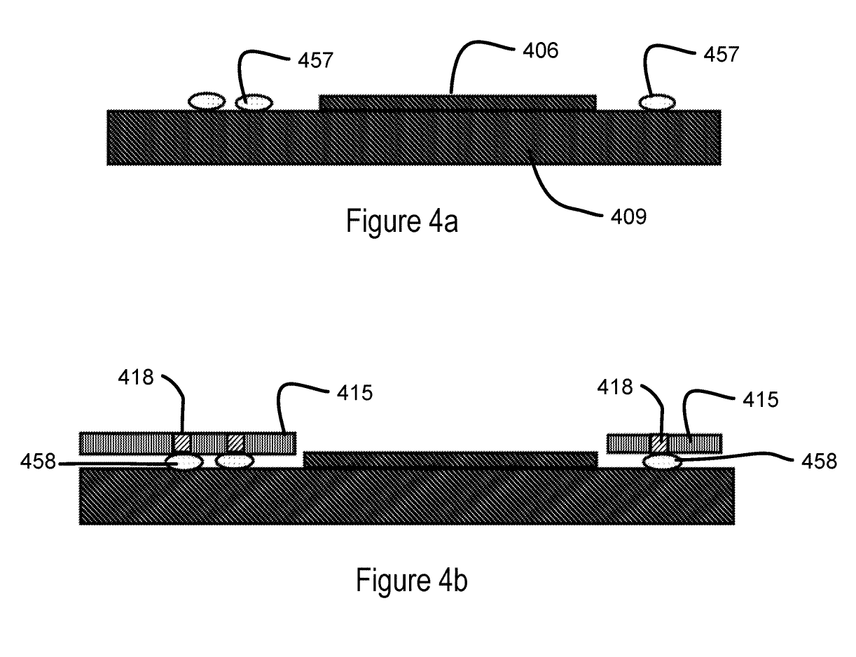

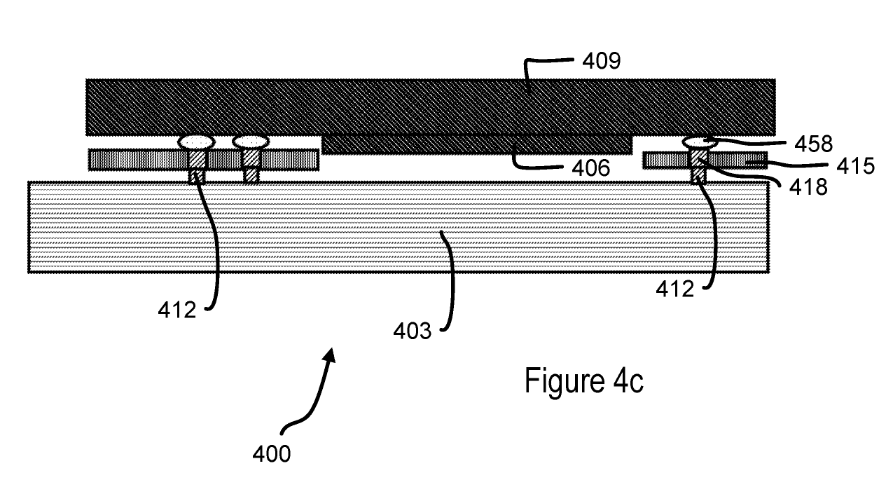

FIGS. 4a-4c depict example stages of the manufacture of an apparatus similar to the example apparatus of FIG. 1, in accordance with various embodiments. In embodiments, a CoC package may include a Tx die 409 and a Tx IC die 406, which may be respectively similar to Tx die 109 and Tx IC die 106. Details of the coupling of the Tx die 409 to the Tx IC die 406 may be similar to those described above with respect to Tx die 109 and Tx IC die 106. The Tx die 409 may have a plurality of LF solder bumps 457 positioned thereon. The LF solder bumps 457 may be made of an LF solder material similar to the LF material described above with respect to FIG. 1.

As shown in FIG. 4b, an interposer may then be positioned on the LF solder bumps. Specifically, the interposer may include an interposer substrate 415 which may be similar to interposer substrate 115. The interposer may further include one or more interposer conductors 418, which may be similar to interposer conductor 118. The interposer may be positioned on the LF solder bumps and then mass reflow may be performed to form LF solder joints 458, which may be similar to LF solder joints 158. Subsequently, capillary underfill may be performed to provide underfill material on or around the Tx IC die 406, the Tx die 409, or the interposer. Alternatively, the interposer conductors 418 may be coupled with the LF solder bumps 457 via a TCNCP process as described above wherein the interposer is positioned on the LF solder bumps 457 and then solder joints 458 are formed via compression and the application of heat.

As shown in FIG. 4c, the combination interposer and CoC package may then be positioned on Cu posts 412 (which may be respectively similar to Cu posts 112) of a substrate 403 (which may be similar to substrate 103). The interposer conductors 418 may be coupled with the Cu posts 412 via a TCNCP process as described above. As shown in FIG. 4c, the apparatus 400 may be similar to apparatus 100 and include a substrate 403, one or more Cu posts 412, one or more interposer conductors 418, an interposer substrate 415, one or more LF solder joints 458, a Tx die 409, and a Tx IC die 406.

FIGS. 4a-4c depict example stages of the manufacture of an apparatus similar to the example apparatus of FIG. 1, in accordance with various embodiments.

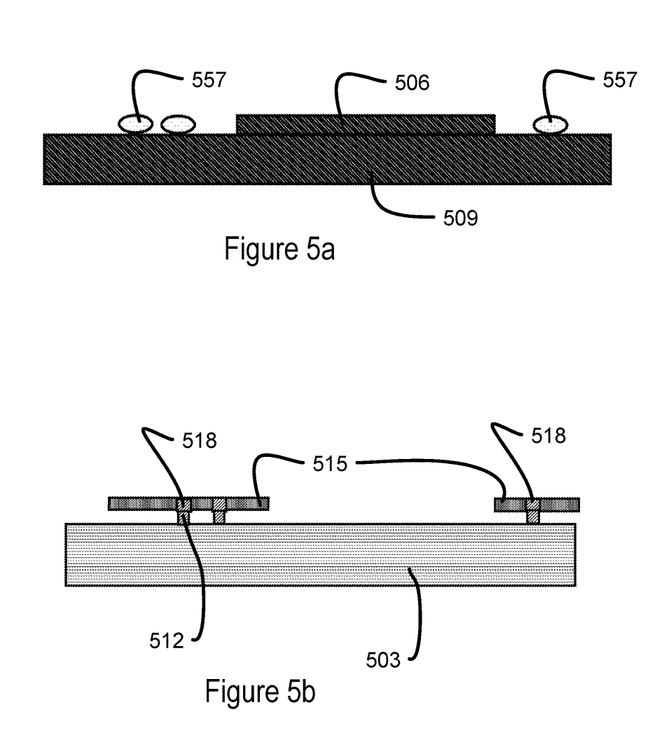

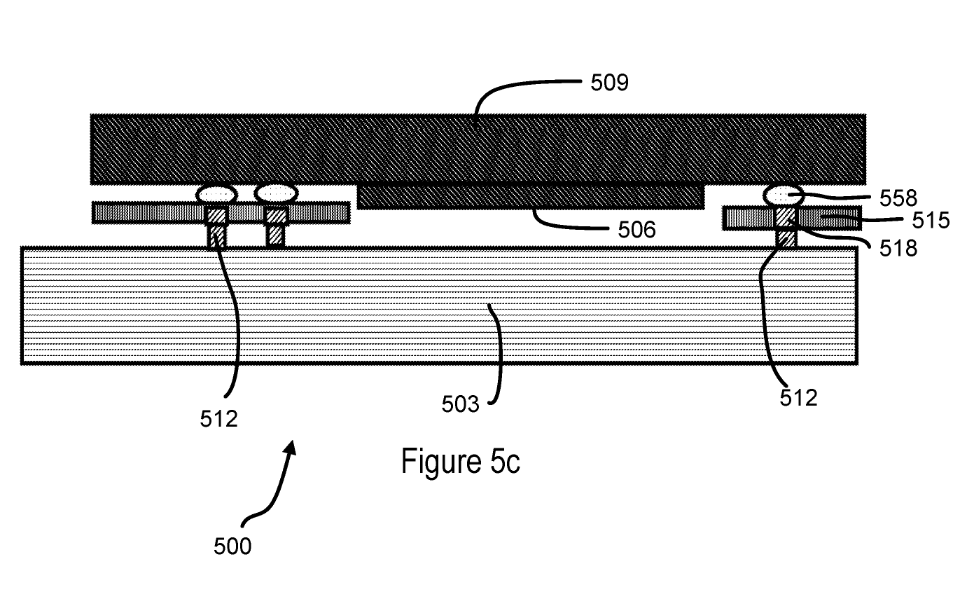

As shown in FIG. 5a, a CoC package may include a Tx die 509, a Tx IC die 506, and one or more LF solder bumps 557, which may be respectively similar to Tx die 409, Tx IC die 406, and LF solder bumps 457.

As shown in FIG. 5b, an interposer (i.e., an interposer including interposer substrate 515 and one or more interposer conductors 518, which may be respectively similar to interposer substrate 415 and interposer conductors 418) may be coupled with one or more Cu posts 512 (which may be similar to Cu posts 412) of a substrate 503 (which may be similar to substrate 403). In embodiments, the interposer conductors 518 may be coupled with the Cu posts 512 through a TCNCP process, a mass reflow process, or some other process. In some embodiments, the interposer conductors 518 may be coupled with the Cu posts 512 by a supplier of the substrate 503, or by a manufacturer of an apparatus such as apparatus 100.

As shown in FIG. 5c, the CoC package, and particularly the LF solder bumps 557, may be coupled with the interposer conductors 518. After the LF solder bumps are placed on the interposer conductors 518, a TCNCP process may be performed to generate the LF solder joints 558 which may be similar to LF solder joints 458. An apparatus 500, which may be similar to apparatus 100, may therefore include substrate 503, one or more Cu posts 512, one or more interposer conductors 518, an interposer substrate 515, one or more LF solder joints 558, a Tx die 509, and a Tx IC die 506.

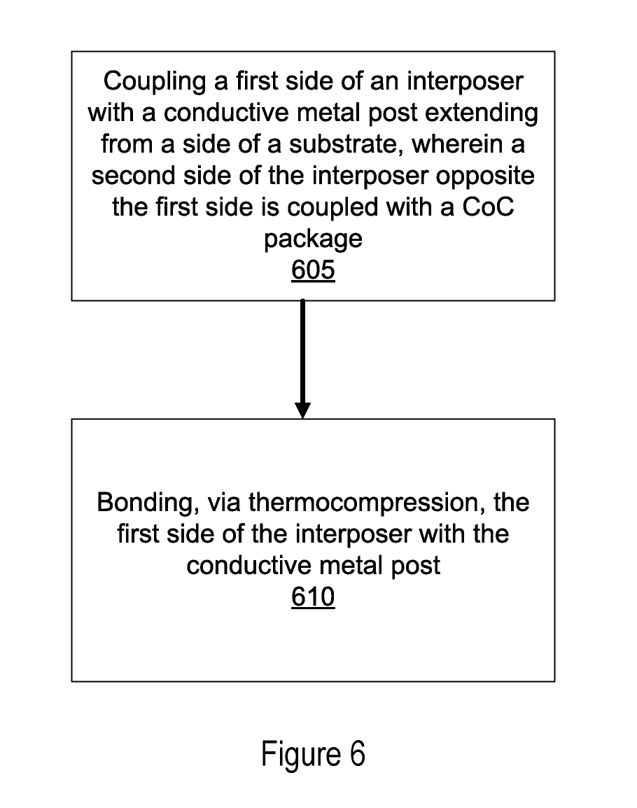

FIG. 6 depicts an example process for manufacturing an apparatus similar to the apparatus of FIG. 1 or 4c, in accordance with various embodiments. Specifically, the process may include coupling a first side of an interposer with a conductive metal post extending from a side of a substrate, wherein a second side of the interposer opposite the first side is coupled with a CoC package at 605. For example, an interposer, and in particular an interposer conductor such as interposer conductor 418, may be coupled with a conductive metal post such as Cu post 412 extending from a side of a substrate such as substrate 403.

The process may then include bonding, via thermocompression, the first side of the interposer with the conductive metal post at 610. For example, an interposer, and particularly an interposer conductor such as interposer conductor 418, may be bonded with a conductive metal post such as Cu post 412 via a TCNCP process as described above.

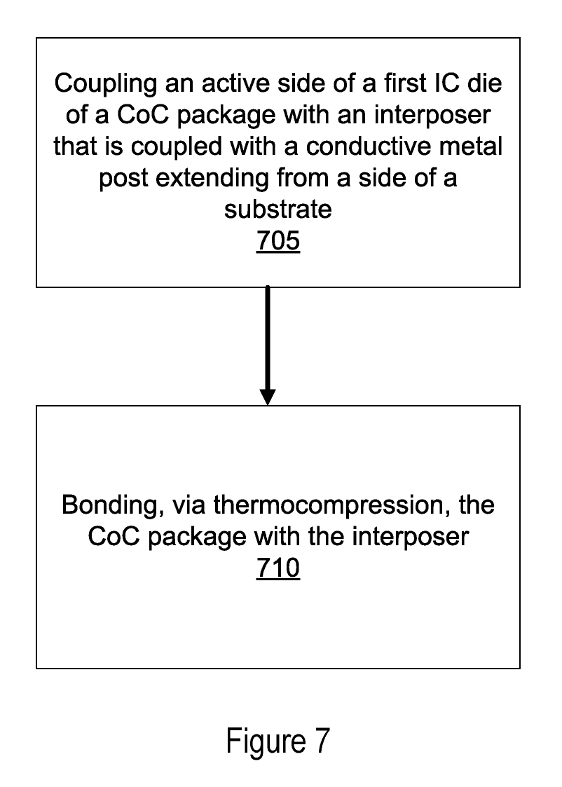

FIG. 7 depicts an alternative example process for manufacturing an apparatus similar to the apparatus of FIG. 1 or 5c, in accordance with various embodiments. Initially, the process may include coupling an active side of a first IC die of a CoC package with an interposer that is coupled with a conductive metal post extending from a side of a substrate at 705. Specifically an active side of an IC die such as Tx die 506 may be coupled with an interposer, and particularly an interposer conductor, such as interposer conductor 518. The interposer may be coupled with a conductive metal post such as Cu post 512 that extends from a side of a substrate such as substrate 503.

The process may then include bonding, via thermocompression, the CoC package with the interposer at 710. Specifically, CoC package may be bonded with the interposer, and thereby the substrate, via a TCNCP process as described above to generate LF solder joints 558.

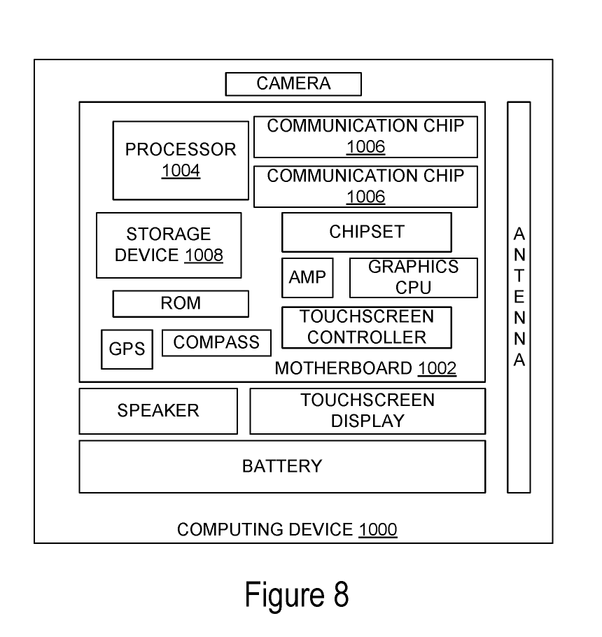

Embodiments of the present disclosure may be implemented into a system using any packages that may benefit from the various manufacturing techniques disclosed herein. FIG. 8 schematically illustrates a computing device 1000, in accordance with some implementations, which may include one or more apparatuses such as apparatus 100, 400, 500, etc. In embodiments, the computing device 1000 may include a CoC package that includes a Tx die such as Tx die 109 or Tx IC die such as Tx IC die 106. In other embodiments, one or more elements such as a processor 1004 may be a CoC package, and may be coupled with a motherboard of the computing device 1000 via an interposer such as the interposer discussed with respect to any one of the preceding Figures.

The computing device 1000 may be, for example, a mobile communication device or a desktop or rack-based computing device. The computing device 1000 may house a board such as a motherboard 1002. The motherboard 1002 may include a number of components, including (but not limited to) a processor 1004 and at least one communication chip 1006. Any of the components discussed herein with reference to the computing device 1000 may be arranged in or coupled with a package such as discussed herein. In further implementations, the communication chip 1006 may be part of the processor 1004.

The computing device 1000 may include a storage device 1008. In some embodiments, the storage device 1008 may include one or more solid state drives. Examples of storage devices that may be included in the storage device 1008 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 1000 may include other components that may or may not be physically and electrically coupled to the motherboard 1002. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 1006 and the antenna may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1006 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 1006 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1006 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1006 may operate in accordance with other wireless protocols in other embodiments.

The computing device 1000 may include a plurality of communication chips 1006. For instance, a first communication chip 1006 may be dedicated to shorter range wireless communications such as Wi-Fi and Bluetooth, and a second communication chip 1006 may be dedicated to longer range wireless communications such as GPS, EDGE, GPRS, CDMA, WiMAX, LTE, EV-DO, and others. In some embodiments, the communication chip 1006 may support wired communications. For example, the computing device 1000 may include one or more wired servers.

The processor 1004 and/or the communication chip 1006 of the computing device 1000 may include one or more dies or other components in an IC package. Such an IC package may be coupled with an interposer or another package using any of the techniques disclosed herein. The term “processor” may refer to any device or portion of a device that processes electronic data from registers and/or memory to transform that electronic data into other electronic data that may be stored in registers and/or memory.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

The following paragraphs provide examples of various embodiments.

Example 1 may include an apparatus comprising: a chip-on-chip (CoC) package that includes a first integrated circuit (IC) die with an active side coupled with an active side of a second IC die; a substrate; a conductive metal post extending from a side of the substrate; and an interposer positioned between, and coupled with the conductive metal post and the active side of the first IC die, wherein an area between an inactive side of the second IC die and the substrate is free of the interposer.

Example 2 may include the apparatus of example 1 and/or some other example herein, wherein the conductive metal post includes copper (Cu).

Example 3 may include the apparatus of example 1 and/or some other example herein, wherein the first IC die is a laser transmit (Tx) die.

Example 4 may include the apparatus of example 1 and/or some other example herein, wherein the second IC die is a laser transmit (Tx) driver to provide on/off control and bias signals to the first die.

Example 5 may include the apparatus of any of examples 1-4 and/or some other example herein, wherein the interposer includes a dielectric material with one or more conductive elements throughout the dielectric material, wherein a first side of one of the one or more conductive elements is coupled with the conductive metal post and a second side of the one of the one or more conductive elements is coupled with a pad of the active side of the first IC die.

Example 6 may include the apparatus of any of examples 1-4 and/or some other example herein, wherein the conductive metal post has a height of approximately 25 micrometers (urn) and approximately 40 urn as measured in a direction perpendicular to the side of the substrate.

Example 7 may include the apparatus of any of examples 1-4 and/or some other example herein, wherein the first IC die and the second IC die are in a face-to-face configuration.

Example 8 may include a method comprising: coupling a first side of an interposer with a conductive metal post extending from a side of a substrate, wherein a second side of the interposer opposite the first side is coupled with a chip-on-chip (CoC) package that includes a first integrated circuit (IC) die with an active side coupled with an active side of a second IC die; and bonding, via thermocompression, the first side of the interposer with the conductive metal post; wherein an area between an inactive side of the second IC die opposite the active side and the side of the substrate is free of the interposer.

Example 9 may include the method of example 8 and/or some other example herein, further comprising coupling the second side of the interposer with the active side of the first IC die.

Example 10 may include the method of example 8 and/or some other example herein, wherein the conductive metal post includes copper (Cu).

Example 11 may include the method of example 8 and/or some other example herein, wherein the first IC die is a laser transmit (Tx) die.

Example 12 may include the method of example 8 and/or some other example herein, wherein the second IC die is a laser transmit (Tx) driver to provide on/off control and bias signals to the first die.

Example 13 may include the method of any of examples 8-12 and/or some other example herein, wherein the interposer includes a dielectric material with one or more conductive elements throughout the dielectric material, and wherein coupling the first side of the interposer with the conductive metal post includes coupling one of the one or more conductive elements with the conductive metal post.

Example 14 may include the method of any of examples 8-12 and/or some other example herein, wherein the conductive metal post has a height of approximately 25 micrometers (urn) and approximately 40 urn as measured in a direction perpendicular to the side of the substrate.

Example 15 may include a method comprising: coupling an active side of a first integrated circuit (IC) die of a chip-on-chip CoC package with an interposer that is coupled with a conductive metal post extending from a side of a substrate; and bonding, via thermocompression, the CoC package with the interposer; wherein the CoC package includes a second IC die having an active side coupled with the active side of the first IC die; and wherein an area between an inactive side of the second IC die opposite the active side and the side of the substrate is free of the interposer.

Example 16 may include the method of example 15 and/or some other example herein, wherein the conductive metal post includes copper (Cu).

Example 17 may include the method of example 15 and/or some other example herein, wherein the first IC die is a laser transmit (Tx) die.

Example 18 may include the method of example 15 and/or some other example herein, wherein the second IC die is a laser transmit (Tx) driver to provide on/off control and bias signals to the first die.

Example 19 may include the method of any of examples 15-18 and/or some other example herein, wherein the interposer includes a dielectric material with one or more conductive elements throughout the dielectric material, and wherein coupling the first side of the interposer with the active side of the first IC die includes coupling one of the one or more conductive elements with a pad of the first IC die.

Example 20 may include the method of any of examples 15-18 and/or some other example herein, wherein the conductive metal post has a height between approximately 25 micrometers (urn) and approximately 40 urn as measured in a direction perpendicular to the side of the substrate.

What is claimed is:

1. An apparatus comprising:
a chip-on-chip (CoC) package that includes a first integrated circuit (IC) die with an active side coupled with an active side of a second IC die;
a substrate;
a conductive metal post extending from a side of the substrate; and
an interposer positioned between, and coupled with the conductive metal post and the active side of the first IC die, wherein an area between an inactive side of the second IC die and the substrate is free of the interposer.

2. The apparatus of claim 1, wherein the conductive metal post includes copper (Cu).

3. The apparatus of claim 1, wherein the first IC die is a laser transmit (Tx) die.

4. The apparatus of claim 1, wherein the second IC die is a laser transmit (Tx) driver to provide on/off control and bias signals to the first die.

5. The apparatus of claim 1, wherein the interposer includes a dielectric material with one or more conductive elements throughout the dielectric material, wherein a first side of one of the one or more conductive elements is coupled with the conductive metal post and a second side of the one of the one or more conductive elements is coupled with a pad of the active side of the first IC die.

6. The apparatus of claim 1, wherein the conductive metal post has a height of approximately 25 micrometers (urn) and approximately 40 urn as measured in a direction perpendicular to the side of the substrate.

7. The apparatus of claim 1, wherein the first IC die and the second IC die are in a face-to-face configuration.

8. A method comprising:
coupling a first side of an interposer with a conductive metal post extending from a side of a substrate, wherein a second side of the interposer opposite the first side is coupled with a chip-on-chip (CoC) package that includes a first integrated circuit (IC) die with an active side coupled with an active side of a second IC die; and
bonding, via thermocompression, the first side of the interposer with the conductive metal post;
wherein an area between an inactive side of the second IC die opposite the active side and the side of the substrate is free of the interposer.

9. The method of claim 8, further comprising coupling the second side of the interposer with the active side of the first IC die.

10. The method of claim 8, wherein the conductive metal post includes copper (Cu).

11. The method of claim 8, wherein the first IC die is a laser transmit (Tx) die.

12. The method of claim 8, wherein the second IC die is a laser transmit (Tx) driver to provide on/off control and bias signals to the first die.

13. The method of claim 8, wherein the interposer includes a dielectric material with one or more conductive elements throughout the dielectric material, and wherein coupling the first side of the interposer with the conductive metal post includes coupling one of the one or more conductive elements with the conductive metal post.

14. The method of claim 8, wherein the conductive metal post has a height of approximately 25 micrometers (urn) and approximately 40 urn as measured in a direction perpendicular to the side of the substrate.

15. A method comprising:
coupling an active side of a first integrated circuit (IC) die of a chip-on-chip CoC package with an interposer that is coupled with a conductive metal post extending from a side of a substrate; and
bonding, via thermocompression, the CoC package with the interposer;
wherein the CoC package includes a second IC die having an active side coupled with the active side of the first IC die; and
wherein an area between an inactive side of the second IC die opposite the active side and the side of the substrate is free of the interposer.

16. The method of claim 15, wherein the conductive metal post includes copper (Cu).

17. The method of claim 15, wherein the first IC die is a laser transmit (Tx) die.

18. The method of claim 15, wherein the second IC die is a laser transmit (Tx) driver to provide on/off control and bias signals to the first die.

19. The method of claim 15, wherein the interposer includes a dielectric material with one or more conductive elements throughout the dielectric material, and wherein coupling the first side of the interposer with the active side of the first IC die includes coupling one of the one or more conductive elements with a pad of the first IC die.

20. The method of claim 15, wherein the conductive metal post has a height between approximately 25 micrometers (urn) and approximately 40 urn as measured in a direction perpendicular to the side of the substrate.
